(19) United States
(12) Patent Application Publication
(10) Pub. No.: US 2018/0249794 A1
(43) Pub. Date: Sep. 6, 2018

(54) COLOR-CHANGEABLE GEMSTONES

(71) Applicant: D. Swarovski KG, Wattens (AT)

(72) Inventors: Michael Brunthaler, Aldrans (AT); Franz Lexer, Axams (AT); Mathias Mair, Völs (AT); Ernst Altenberger, Kolsass (AT)

(21) Appl. No.: 15/758,407

(22) PCT Filed: Aug. 31, 2016
(86) PCT No.: PCT/EP2016/070507

§ 371 Date: Apr. 24, 2018

(30) Foreign Application Priority Data
Sep. 9, 2015 (EP) 15184408.1

(51) Int. Cl. A44C 17/00; A44C 15/00; C23C 14/10; C23C 14/08; C23C 14/30

(52) U.S. Cl. CPC A44C 17/008; A44C 15/0015; C23C 14/30; C23C 14/10; C23C 14/083; A44C 17/007

(57) ABSTRACT

The invention relates to a decorative ornamental element containing a transparent plano-convex gemstone, a wavelength-selective layer and a color-changeable seating surface, thus being able to cause aesthetic effects and signal effects by color changes. The ornamental element is characterized by a high brilliance and decorative color effect.

### FIELD OF THE INVENTION

The invention relates to a decorative ornamental element containing a transparent gemstone, a wavelength-selective layer and a color-changeable seating surface, and being able to cause aesthetic effects by color changes.

### PRIOR ART

The color design of decorative gemstones is usually effected by the use of tinted gemstones. However, it is also known that the color effect of the gemstone changes in transparent gemstones in connection with a colored underground. The light refracted by the transparent material and the color of the underground become superimposed. If the color of the underground is changeable, the color effect of the gemstone can be varied.

The achievement of aesthetic effects becomes more important also in functional fields. For example, wearable technology is a field of application for aesthetic effects. In particular, a color change in combination with a brilliant appearance (see below) is desirable. From EP 1 086 269 B1, it is known that a changed optical effect of glass elements occurs from the color of a textile underground in combination with glass elements applied thereto. It is not the object of EP 1 086 269 B1 to provide brilliant gemstones. US 2012/01133676 A1 describes a reflective display consisting of a multilayer structure. The use of color filters under ambient light varies the proportions of reflected and transmitted light in the layers and thus the whole reflected color. It is not the object of the application to provide brilliant gemstones. From CN201700538 (U), an earring is known as a jewel in which color effects can be achieved by means of a battery, an electric circuit and color-changeable LEDs. It is not the object of CN201700538 (U) to provide brilliant gemstones. GB 798,080 A discloses a gemstone coated on the backside, which obtains its effect from the ambient light incident on the gemstone from above. US 2007/0274160 A1 describes a clock ornamented with illuminated gemstones.

It is the object of the present invention to provide a color-switchable composite body that combines a color change with a brilliant appearance (see below).

### DESCRIPTION OF THE INVENTION

Surprisingly, it has been found that gemstones obtain a brilliant appearance by the application of a wavelength-selective layer with specific reflection and transmission properties, and by the combination thereof with a color-switchable seating surface. According to the invention, a “brilliant appearance” is understood to mean a reflection behavior in which not only the light is diffusely reflected, but also singular accentuated points of reflected light are present. The composite bodies according to the invention not only have an improved aesthetic effect, but are very much suitable as optical signaling devices (see below).

Therefore, the present invention relates to a decorative ornamental element containing a) a transparent gemstone with a plano-convex geometry, b) a wavelength-selective layer, and c) a color-changeable seating surface. The components a) to c) of the decorative ornamental element are preferably bonded with one another by an adhesive. If the adhesive is directly applied to the transparent gemstone, as in a preferred embodiment, the deviation of the refractive index of the adhesive from the refractive index of the decorative ornamental element is less than 20%. If the difference in refractive index is too large, undesirable reflection losses occur. In a preferred embodiment, the decorative ornamental element essentially consists of the components a) to c) in the mentioned sequence, in which the components a) to c) are preferably bonded to one another with an adhesive.

FIG. 1 shows a possible design combination of the decorative ornamental element (composite body), the reference symbols having the following meanings: A) switchable ornamental element, B) plano-convex gemstone, C) wave-length-selective layer, D) color-changeable seating surface.

Possible applications of this invention are in both aesthetic and functional fields. For example, the invention can be employed in the field of wearable technology.

Products in this field can often monitor particular measuring values by means of sensory control elements. That a critical measured value has been reached could be signaled, for example, by a color change of a display. Critical parameters may be the pulsation, the body temperature, the caloric consumption, electromagnetic radiation and other quantities detectable by sensors.

One possible application of the decorative ornamental element (a composite body) according to the invention is represented, for example, by bracelets equipped with sensors that change the color of the seating surface when a critical measured value is reached. The bracelet thereby obtains a color-changeable (=switchable) appearance. Not only bracelets, but also jewels such as bangles or necklaces, for example, are conceivable in this embodiment.

The application of the decorative ornamental element is not limited to the field of wearable technology using sensory control elements. The ornamental elements may also be used in bracelets or necklaces under purely aesthetic points of view. The connection of a transparent gemstone with a wavelength-selective layer and a color-changeable seating surface enables not only the use as a signaling element, but opens a variety of possible applications in view of aesthetic and design.

Preferably, the transparent gemstone has a faceting to enhance the brilliant appearance. In the preferred plano-convex embodiment, the light shines through the gemstone optimally in terms of surface distribution. According to the invention, a “plano-convex geometry” is understood to mean that the seating surface of the gemstone is flat. Its upper side has predominantly regions with a convex curvature and has facets. In a preferred embodiment, the regions having a predominantly convex curvature correspond to at least 50% of the surface, more preferably at least 70%, even more preferably at least 80%, and 100% are particularly preferred. In the center of the upper side, the gemstone may have a facet parallel to the seating surface, or concave curvatures. Concave curvatures could also be present laterally in the peripheral region (see below), for example, to fit the gemstones into a setting. In round gemstones, the peripheral region is often referred to as the “girdle”.

Preferably, the inclination angle α of the first facet of the transparent faceted gemstone to the base surface or horizontal seating surface of the gemstone is within an angular range of 10° to 40° (cf. also FIGS. 2 and 3). This has the advantage that the homogeneity of the color is well maintained even in a lateral view on the gemstone of up to about 35°. When the gemstone lies horizontally flat on its planar side, then the preferred inclination angle α is the acute angle included with the horizontal seating surface. In contrast, the viewing angle is measured from the vertical direction. The so-called peripheral region of a gemstone (RB =peripheral region, FIG. 3) preferably has an inclination angle β of 80° to 100°. In an exemplary way, FIG. 2 shows the contour of a gemstone without a peripheral region. In an exemplary way, FIG. 3 shows the peripheral region with an inclination angle β of 90°.

For the optical effects, the transparency of the gemstone is an essential property. The transparency of the gemstone is related to its transmission properties. According to the invention, the “transparency” of the gemstone is understood to mean a transmission of the incident light of at least 50%, preferably more than 80%.

According to the invention, the components of the decorative ornamental element are preferably bonded together with an adhesive, more preferably UV-curing (280-380 nm) or light-curing (380-780 nm) adhesives, because they cure very quickly under the action of UV or visible light, respectively. Both the UV-curing and the light-curing adhesives are adequately familiar to the skilled person. For optical reasons, the adhesive should be sufficiently transparent in order that as much light as possible arrives at the wavelength-selective layer. Preferably, it has a transparency of at least 80%, more preferably at least 90%. The use of UV-curing or light-curing acrylate adhesives, especially of modified urethane acrylate adhesives, is even more preferred according to the invention. They are sold by various companies, for example, by Delo under the designation Delo-Photobond® GB 368, an adhesive that can be cured by UV light and visible light within a range of 320-420 nm. Other adhesives can also be employed according to the invention, for example, epoxy resin adhesives, such as EPO-TEK® 301-2 from the company EPDXY-Technology. The methods for determining the transparency are adequately familiar to the skilled person. It may be explicitly mentioned here that there are other possibilities of bonding the components of the decorative ornamental element together, for example, mechanical ones, for example by suitable fixtures, so that bonding with an adhesive is not necessarily needed.

In a preferred embodiment, the wavelength-selective layer (see below) is directly applied to the gemstone on the planar side opposed to the faceting (FIG. 1). This coated side is preferably bonded with the color-changeable seating surface. In an alternative embodiment, which is preferred according to the invention, the wavelength-selective layer is applied to the color-changeable seating surface. Then, the thus prepared color-changeable seating surface is preferably bonded with the transparent gemstone. However, the bonding of the individual parts is not necessarily needed.

Preferably, the wavelength-selective layer is a wavelength-selective coating (see below) or a wavelength-selective film (see below). Wavelength-selective coatings have proven advantageous because they have very good reflection and transmission properties. The wavelength-selective film (see below) may be employed either alternatively or in addition to a wavelength-selective coating (see below). Preferably, it is bonded with the color-changeable seating surface and with the transparent gemstone by adhesive layers. However, the bonding of the individual parts is not necessarily needed.

Preferably, electronically switchable displays are used as the seating surface; thus, a color change can be realized by electronic addressing. It is preferred according to the invention that this change takes place between white and black colors. The principle of action of the color-changeable gemstone is shown in FIGS. 4 and 5. When the seating surface is black, as in FIG. 4, then the light fraction transmitted through the wavelength-selective layer is predominantly absorbed, and only the light fraction reflected at the wavelength-selective layer can be conceived. When the seating surface is white, as in FIG. 5, the light fraction transmitted through the wavelength-selective layer is reflected at the white surface and becomes superimposed with the light fraction reflected at the wavelength-selective layer to produce a new color. The white background preferably exhibits diffuse reflection. This has the advantage that the color change can be detected in a larger angular range.

For example, bistable displays (see below), such as e-paper or E-Ink®, are also suitable as seating surfaces. They have the advantage that they require energy only during the color change itself. This is advantageous for wearable technologies with their low energy resources. However, other display technologies, such as OLED, TFT, LCD, can also be employed.

The L*a*b* color space according to DIN EN ISO 11664-4 is used to measure the color change of the decorative ornamental element. If the color location of the ornamental element is quantitatively determined, such as for the white and black seating surface as preferred according to the invention, the color location p=(L*ₚ, a*ₚ, b*ₚ) is obtained from the measured ornamental element when the seating surface is white, and when the seating surface is black, the color location v=(L*ᵥ, a*ᵥ, b*ᵥ) is obtained. The color change is calculated by the distance of color location “p” from color location “v”. The distance of color location “p” from color location “v” is ΔE={square root over ((L*ₚ-L*ᵥ²+(a*ₚ-a*ᵥ)²+(b*ₚ-b*ᵥ)²)}. A distance ΔE that is larger than or equal to 5, i.e., ΔE≥5, is preferred according to the invention for the color change to be discernible by the human eye.

The invention also relates to the process for changing the color of a decorative ornamental element by changing the color of the seating surface by means of an electronic circuit.

### Transparent Gemstone

The transparent gemstone can be made of a wide variety of materials, for example, transparent glass, plastic, transparent ceramic or a transparent gem. Transparent gemstones made of glass or plastic are preferred according to the invention, because they are lowest cost. Glass is preferred according to the invention because of its excellent optical effect.

Glass

The invention is not limited in principle with respect to the composition of the glass, as long as it is transparent. “Glass” means a frozen supercooled liquid that forms an amorphous solid. The refractive index of the glass is preferably within a range of from 1.5 to 1.9. According to the invention, both oxidic glasses and chalcogenide glasses, metallic glasses or non-metallic glasses can be employed. Oxynitride glasses may also be suitable. The glasses may be one-component (e.g., silica) or two-component (e.g., alkali borate glass) or multicomponent (soda lime glass) glasses. The glass can be prepared by melting, by sol-gel processes, or by shock waves. The methods are known to the skilled person. Inorganic glasses, especially oxidic glasses, are preferred according to the invention. These include silicate glasses, borate glasses or phosphate glasses. Lead-free glasses are particularly preferred. For the preparation of the faceted transparent gemstones, silica glasses are preferred. Silica glasses have in common that their network is mainly formed by silicon dioxide (SiO₂). By adding further oxides, such as alumina or different alkali oxides, the alumosilicate or alkali silicate glasses are formed. If phosphorus pentoxide or boron trioxide are the main network formers of a glass, it is referred to as a phosphate or borate glass, respectively, whose properties can also be adjusted by adding further oxides. These glasses can also be employed according to the invention. The mentioned glasses mainly consist of oxides, which is why they are generically referred to as oxidic glasses. In a preferred embodiment according to the invention, the glass composition contains the following components: (a) about 35 to about 85% by weight SiO₂; (b) 0 to about 20% by weight K₂O; (c) 0 to about 20% by weight Na₂O; (d) 0 to about 5% by weight Li₂O; (e) 0 to about 13% by weight ZnO; (f) 0 to about 11% by weight CaO; (g) 0 to about 7% by weight MgO; (h) 0 to about 10% by weight BaO; (i) 0 to about 4% by weight Al₂O₃; (j) 0 to about 5% by weight ZrO₂; (k) 0 to about 6% by weight B₂O₃; (I) 0 to about 3% by weight F; (m) 0 to about 2.5% by weight Cl. All stated amounts are to be understood as giving a total sum of 100% by weight.

The faceting of the glass objects is obtained by grinding and polishing techniques that are adequately familiar to the skilled person. For example, a lead-free glass, especially one produced by the company Swarovski, is suitable according to the invention.

Plastic

As another raw material for the preparation of the transparent gemstone, transparent plastics can be employed. All plastics that are transparent after the curing of the monomers are suitable according to the invention; these are adequately familiar to the skilled person. Among others, the following materials are used: acrylic glass (polymethyl methacrylate, PMMA), polycarbonate (PC), polyvinyl chloride (PVC), polystyrene (PS), polyphenylene ether (PPO), polyethylene (PE), poly-N-methylmethacrylimide (PMMI). The advantages of the transparent plastics over glass reside, in particular, in the lower specific weight, which is only about half that of glass. Other material properties may also be selectively adjusted. In addition, plastics are often more readily processed as compared to glass. Drawbacks include the low modulus of elasticity and the low surface hardness as well as the massive drop in strength at temperatures from about 70 ° C., as compared to glass. A preferred plastic according to the invention is poly-N-methylmethacrylimide, which is sold, for example, by Evonik under the name Pleximid® TT70. Pleximid® TT70 has a refractive index of 1.54, and a transmittance of 91% as measured according to ISO 13468-2 using D65 standard light.

Geometry

The geometric design of the transparent gemstone is not limited in principle and strongly depends on design aspects. The basic shape of the gemstone is preferably square, rectangular or round. According to the invention, the gemstone preferably has a faceted surface, because facets are advantageous to a brilliant appearance. Gemstones with a plano-convex geometry are preferred according to the invention, because the light shines well through such gemstones. In connection with the facets, a particularly brilliant appearance is obtained in this case. If the facets have a preferred inclination angle α of 10° to 40°, a total impression homogeneous in color is given even in a lateral view. The geometric shape of the facets is not limited in principle, but facets in the form of a trapezoid or triangle as well as rectangular or square facets are preferred.

### Wavelength-Selective Layer

The wavelength-selective layer is essentially responsible for the fact that the gemstone obtains its brilliant appearance and thereby is conceived as a gemstone in the first place. It is preferably provided between the transparent gemstone and the color-changeable seating surface. Preferably, the wavelength-selective layer is a wavelength-selective film or a wavelength-selective coating. The wavelength-selective coating is preferably prepared by PVD, CVD or wet-chemical methods. However, a wavelength-selective layer may also be obtained from a microstructured surface. The methods of microstructuring are well known to the skilled person.

As a result of the reflection and transmission of a defined range of the visible light spectrum, the wavelength-selective layer acts as a filter. The optical element gains brilliance thereby and appears in a particular color to the viewer. The brilliance is further supported by the faceting of the plano-convex object. In a preferred embodiment of the invention, the wavelength-selective layer reflects and transmits a fraction of the light in the range of 380 to 780 nm, i.e., in the visible range. Particularly preferred according to the invention is a wavelength-selective layer that has an average reflectance of less than 75% in the visible wavelength range of from 400 to 700 nm. According to the invention, the “average reflectance” is understood to mean the ratio of the integral of the reflection curve (FIG. 6, crosshatched area) of the wavelength-selective layer to the integral of the basically maximum possible reflection curve (FIG. 6, area under the dotted line) over respectively the same wavelength range in percent. The integration interval is the wavelength range of from 400 nm to 700 nm. For an average reflectance of the wavelength-selective layer above 75%, the color-changeable seating surface has a lesser influence on a visible color change of the decorative ornamental element because of the stronger reflection at the wave-length-selective layer. An average reflectance of less than 75% enhances the color change effect and is therefore preferred according to the invention. FIG. 6 shows an example of an average reflectance of less than 75%; the integral below the dotted line in the wavelength range of from 400 nm to 700 nm is normalized to 100%. FIG. 7 shows an example of a not quite optimum average reflectance that is above 75%.

The incident light is partially reflected at the wavelength-selective layer, and partially transmitted through it. The wavelength-selective layer is of great importance to the dispersion of the light and the brilliant appearance of the decorative ornamental element. A diffuse reflection at the wavelength-selective layer reduces the brilliant appearance because accentuated points of light do not form. Therefore, the fraction of scattered light in the reflected light of the wavelength-selective layer is preferably smaller than 5%.

The wavelength-selective layer is preferably applied directly to the flat side of the gemstone, or alternatively to the color-changeable seating surface.

The wavelength-selective layer has the property that the reflection at it is angle-dependent. A change in the viewing angle causes a change of the reflected spectrum. FIG. 8 shows the change of the reflected spectrum for different viewing angles for coating variant 1 of Table 1 (see below). A viewing angle of 0° corresponds to a vertical view onto the gemstone, and a viewing angle of 85°, measured from a vertical axis, corresponds to a view from a side. The change of the reflected spectrum of the wavelength-selective layer as a function of the viewing angle in connection with faceted gemstones as preferred according to the invention has the effect that different color fractions are reflected through the facets. If the preferred inclination angle α of the facet is within an angular range of from 10° to 40°, the homogeneity of the color is retained even in a lateral view.

If a UV-curing or light-curing adhesive is used as the bonding element of the individual components of the decorative ornamental element, then the transmission property of the wavelength-selective layer is of importance to the curing of the adhesive. In order to be able to bond the individual components of the decorative ornamental element with UV- or light-curing adhesive, it is required that the wavelength-selective layer is sufficiently transparent. It is preferred according to the invention that the wavelength-selective layer transmits at least 20% in a wavelength range of from 360 nm to 420 nm.

Wavelength-Selective Films

Wavelength-selective films can be employed alternatively or in addition to the wavelength-selective coating (see below). Wavelength-selective films as reflection filters are commercially available under the designation “Radiant Light Film”. These are multilayered polymeric films that can be applied to other materials. These optical films are Bragg mirrors and reflect a high proportion of the visible light and produce color effects. The different wavelengths of the light are reflected as a function of the light incidence angle, and interference phenomena occur. Thus, the color changes as a function of the viewing angle.

Particularly preferred films according to the invention consist of multilayered polymeric films whose outermost layer is a polyester. Such films are sold, for example, by the company 3M under the name Radiant Color Film CM 500, under the Article Nos. 76917, 76922, 76924 and 76926. The films have a reflection interval of 590-740 nm or 500-700 nm.

Wavelength-selective films based on absorption rather than reflection can be additionally used as absorption filters, for example, the film Roscolux #80 Primary Blue of the company Rosco. Color shifts can be achieved by absorption filters.

The wavelength-selective film is preferably bonded with the color-changeable seating surface and the transparent gemstone by means of a transparent adhesive. In a preferred embodiment, the refractive index of the adhesive deviates by less than ±20% from the refractive index of the transparent gemstone. In a particular preferred embodiment, the deviation is smaller than ±10%, even more preferably smaller than ±5%. This is the only way to ensure that reflection losses because of the different refractive indices can be minimized.

The refractive indices can also be matched to one another by roughening the respective boundary layers (moth eye effect). So-called “moth eye surfaces” consist of fine nap structures that change the refraction behavior of the light, not suddenly, but continuously in the ideal case. The sharp boundaries between the different refractive indices are removed thereby, so that the transition is almost fluent, and the light can pass through unhindered. The structural sizes required for this must be smaller than 300 nm. Moth eye effects ensure that the reflection at the boundary layers is minimized, and thus a higher light yield is achieved in the passage through the boundary layers.

Wavelength-Selective Coating

Because of their reflection and transmission properties, wavelength-selective coatings are also suitable for the construction of a wavelength-selective layer. The coating materials are well known to the skilled person. In a preferred embodiment of the invention, the wavelength-selective coatings contain at least one metal and/or metal compound, preferably with a structure comprising a sequence of SiO₂ and TiO₂ layers. Other possible coating materials in addition to metals and metal oxides include, for example, metal nitrides, metal fluorides, metal carbides or any combination of such compounds in any order, which are applied to the gemstones or the color-changeable seating surface by one of the common coating methods. Successive layers of different metals or metal compounds can also be applied. The methods of preparing coatings and the coatings themselves are adequately known to the skilled person. According to the prior art, these include, among others, PVD (physical vapor deposition) methods, CVD (chemical vapor deposition) methods, paint-coating methods and wet chemical methods. PVD methods are preferred according to the invention.

The PVD methods are a group of vacuum-based coating methods or thin-layer technologies, which are adequately familiar to the skilled person and are employed in the optical and jewelry industries, in particular, for coating glass and plastics. In a PVD process, the coating material is transferred to the gas phase. The gaseous material is subsequently passed to the substrate to be coated, where it condenses and forms the target layer.

The coating materials are thermally transferred to the gas phase by heating a source filled with the coating material, for example, by resistive or inductive heating, and heating the material to the boiling point. Another thermal evaporation method is the so-called electron beam evaporation, in which the evaporation energy is generated by means of a high energy electron beam. For example, the model BAK1101 from the company Evatec or Balzers BAK760 are suitable for the thermal evaporation methods.

Sputtering is another process for transferring the coating material to the gas phase. In the sputtering method, high energy gas ions are accelerated onto the surface of a target in a vacuum chamber. The target is made of the coating material. Atoms are released from the target by mechanical impacts. The released particles impinge on the substrate to be coated and condense on the surface. For example, the model Radiance of the company Evatec is suitable for sputtering.

With some of these PVD methods (sputtering, laser beam evaporation, thermal vapor deposition etc.), low process temperatures can be realized. Thus, it is possible to coat even low-melting plastics. A wide variety of metals can be deposited in this way in a very pure form in thin layers. If the process is performed in the presence of reactive gases, such as oxygen, then metal oxides may also be deposited. A typical layer system may be constituted of only one, but also of a large number of layers, depending on the requirement for the function and optical appearance.

For the construction of a wavelength-selective coating, substantially absorption-free dielectric materials are suitable, for example. The desired reflectance and transmittance can be adjusted by a suitable selection of coating materials, number of layers and layer thicknesses. For the substantially absorption-free dielectric materials, the following coating materials are preferably suitable: MgF₂, SiO₂, CeF₃, Al₂O₃, CeO₃, ZrO₂, Si₃N₄, Ta₂O₅, TiO₂, or any combination of these compounds in any sequence of layers.

It is further possible to use absorbing materials in the wavelength-selective layer. This results in further possible designs in view of the coloring. Suitable absorbing materials in the layer system include, for example, Cr, Cr₂O₃, Fe, Fe₂O₃, Al, Au, SiO, Mn, Si, Cu, Ag, Ti, or any combination of these compounds in any sequence of layers.

By combining the wavelength-selective layer with an absorbing film, the color can be additionally changed to advantage. Depending on the structure, the absorption film is provided between the wavelength-selective layer and the color-changeable seating surface, or between the wavelength-selective layer and the decorative gemstone.

Preferred according to the invention are coatings constituted by dielectric materials that transmit or reflect only particular fractions of the visible light because of interference phenomena, and thereby appear colored, for example, a multiple sequence of TiO₂ and SiO₂. The number of layers and the layer thickness can vary highly depending on the color. A wide variety of colors with high or low color saturation are possible.

### Color-Changeable Seating Surface

The color-changeable seating surface is preferably an electronically switchable display, which changes color upon electronic addressing. The color change preferably takes place between two colors, more preferably between the colors white and black. The change between the colors white and black enables a well visible color change of the decorative ornamental element. According to the invention, the color change may also take place between other colors.

Preferred electronically switchable displays include bistable displays, because energy must be provided only for the switching during the color change in such displays. The changed state is maintained without energy expenditure. If the color-changeable gemstones are operated with a battery or photovoltaic cells, an energy-saving supply is of great importance.

Bistable displays include, for example, e-paper, E-Ink or bistable LCD. “E-paper” refers to electronic paper. This is a passive display technology that is based on reflection and therefore not self-luminous. E-paper contains charged white and/or charged black microcapsules contained in a viscous medium. Upon a brief application of an electric voltage, the charged microcapsules change their positions and thereby become visible or disappear: Thus, the display can change its color on the basis of the effect of electrophoresis, for example, between white and black. The use of microcapsules also allows to use a flexible plastic instead of glass as a support material. E-Ink® is a product designation of the E Ink® Corporation and therefore a synonym for the designation e-paper. Suitable e-papers include, for example, the product AEP0213021201042_001 of the company Admatec.

Liquid crystal displays (LCDs) can also be employed as a color-changeable seating surface. They are widely employed, for example, in monitors, computer games and above all in mobile devices of communication and consumer electronics. There are both LCDs with power supply, and LCDs with a bistable design. LCD displays are based on liquid crystal cells. In this display type, the polarization plane of the light is rotated. Upon application of an electric field to the liquid crystal cell, the liquid crystal molecules orient themselves in the electric field, whereby the transparency of the liquid crystal cell to light can be controlled.

Preferred are bistable LCDs, which maintain their display state without additional power supply. In this display type, energy is needed only for changing the orientation of the liquid crystals. Once brought into position, these retain their orientation until they are newly oriented in the next adjustment. For example, the product LS010B7DH01 of the company Sharp can be used as a bistable LCD display.

Organic light emitting diodes (OLEDs) are also suitable as a color-changeable seating surface. An OLED is a luminous thin-layer device, producing light from electric charges by utilizing electroluminescence. OLEDs consist of an organic layer or of a number of different thin organic layers embedded between two contacts. One of the contacts must be transparent to enable the generated light to escape. The OLED technology is employed, for example, in screens and displays.

Other display variants, for example, LEDs or TFT-controlled displays, are also suitable for use according to the invention. Generally, both single pixel and multi pixel systems are suitable. The displays are well known to the skilled person.

Further, as the color-changeable seating surface, temperature-dependent color-changeable materials may be employed, for example, thermochromic sheets, paints or inks. The color change may be reversible. A color change is produced by heating; when the material cools down, the original color returns. Suitable thermochromic sheets include, for example, the products R20C5B, R25C5B, R29C4B, R30C5B, R35C1B, R35C5B, R40C5B and R45C5B of the company LCR Hallcrest, and suitable thermochromic inks include, for example, the product JC21A of the company LCR Hallcrest. These thermochromic materials are well known to the skilled person.

Decorative ornamental elements with hidden messages, such as texts or signs, are further interesting applications. For example, thermochromic sheets are provided with printed messages that become visible only by a color change. A text message printed, for example in black color is visible, for example, with a white seating surface. When the color changes from white to black, the text message can no longer be seen. This effect can be used, for example, for company logos, company designations or other signs.

In addition to the color-changeable seating surfaces already mentioned, photo-chromic materials, such as sheets or paints, may also be used. “Photochromism” means a light-induced reversible conversion. The trigger for the conversion is mostly UV light.

### LIST OF FIGURES

FIG. 1: Structure of the decorative ornamental element A: B=gemstone, C=wavelength-selective layer, D=color-changeable seating surface.

FIG. 2: Inclination angle α of the first facet.

FIG. 3: Inclination angle α of the first facet as well as peripheral region and inclination angle β.

FIG. 4: Fundamental beam path for a black seating surface; A is the incident light, and B is the reflected light.

FIG. 5: Fundamental beam path for a white seating surface; A is the incident light, and B is the reflected light.

FIG. 6: Example of an average reflectance of less than 75%.

FIG. 7: Example of an average reflectance of more than 75%.

FIG. 8: Angular dependence of the reflected spectrum of Table 1, viewing direction from 0° to 85°.

FIG. 9: Measuring set-up for determining the color location: (1) Ornamental element, (2) measuring camera, (3) hemisphere with reflecting inner surface, (4) light source, (5) opening with 2×15°, (6) diameter of the hemisphere, (7) distance from center of hemisphere to camera.

FIG. 10: Measuring arrangement for determining the brilliance: (1) Ornamental element, (2) measuring camera, (3) diffuser, (4) light source, (5) semitransparent mirror, (6) distance from ornamental element to diffuser, (7) distance from ornamental element to measuring camera.

FIG. 11: Measurement of brilliance with coating variant 2 and a white seating surface.

FIG. 12: Measurement of brilliance with coating variant 2 and a black seating surface.

FIG. 13: Measurement of brilliance without a wavelength-selective layer and with a white seating surface.

FIG. 14: Measurement of brilliance without a wavelength-selective layer and with a black seating surface.

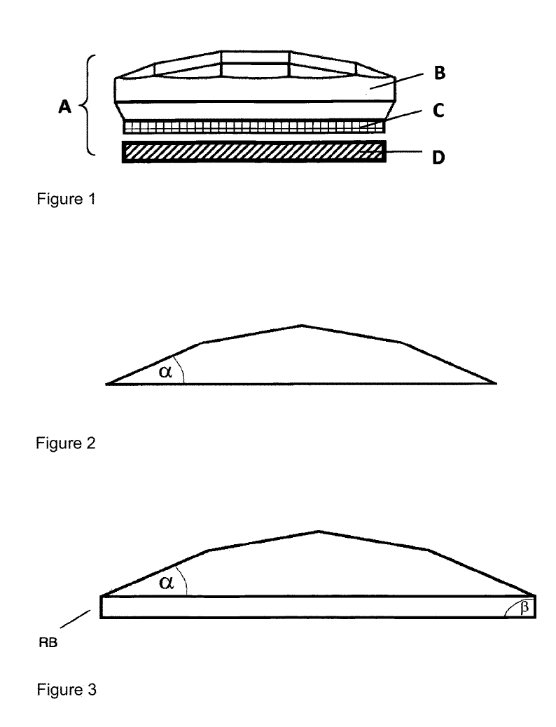

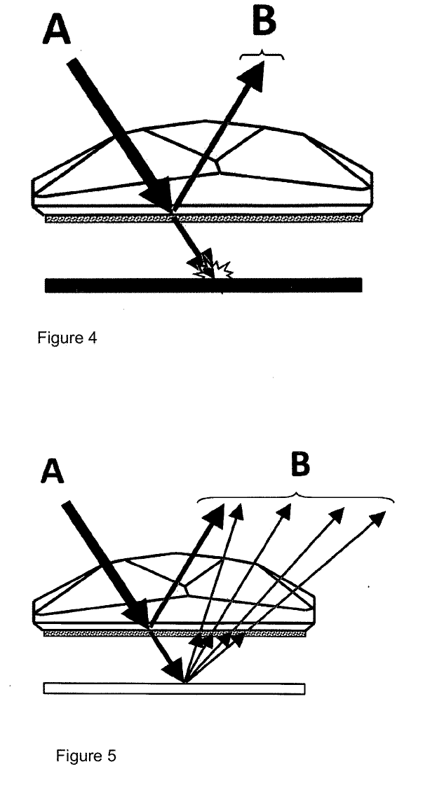

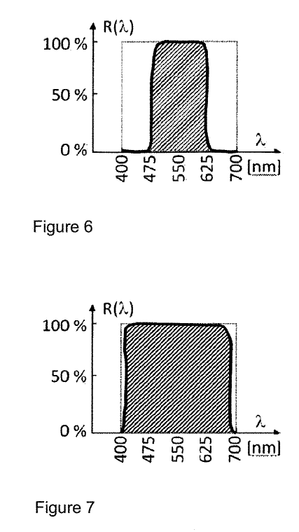

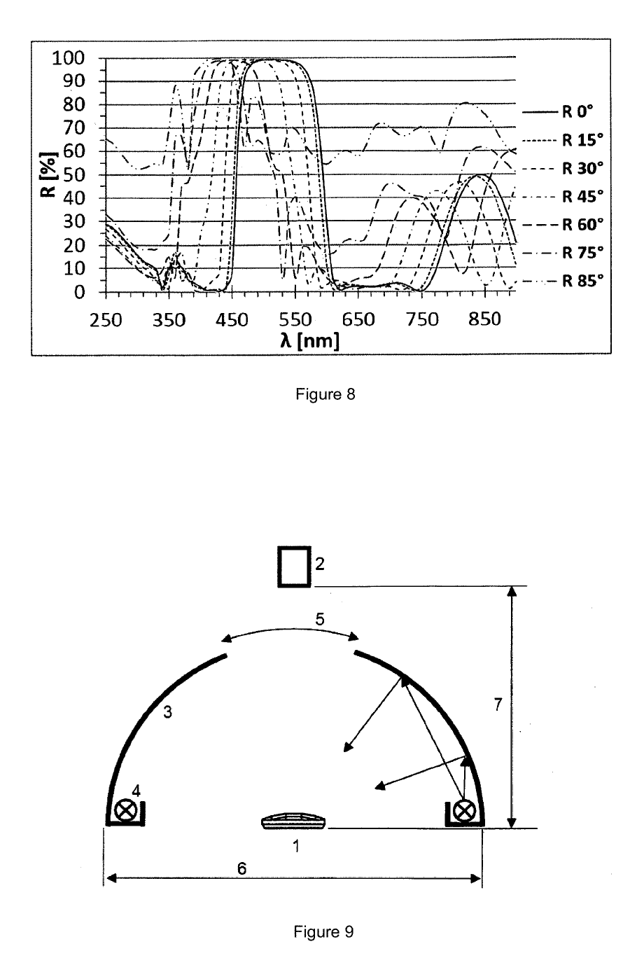

### EXAMPLES ACCORDING TO THE INVENTION

Different decorative ornamental elements were examined in various measurements. Ornamental elements were constructed from a transparent gemstone, a wavelength-selective layer and a color-changeable seating surface. The wave-length-selective layer was designed as a wavelength-selective PVD coating (see above). Black or white sheets were used as the color-changeable seating surface for the measurements for reasons of practicability. In their optical properties, the sheets correspond to an e-paper and enabled a small and compact measuring set-up. As a white sheet, the product 303/W, and as a black sheet, the article 303/B of the company Coroplast were used.

In all measurements, the transparent circular faceted flatback gemstone Chess-board Circle (Art. No. 2035 with 14 mm diameter) of the company Swarovski was used as the transparent gemstone.

The gemstones were subjected to vapor deposition by a PVD process with the cubic coating plant (Balzers BAK760), see position C in FIG. 1. The layer materials were evaporated by means of an electron beam evaporator. The deposition on the gemstone surface was supported by accelerated oxygen ions from an ion source of the type Veeco Mark II.

The wavelength-selective PVD coating had a sufficient UV transparency that enabled the adhesive to be cured. A PVD-coated Chessboard Circle gemstone was applied with a commercially available transparent UV-curing adhesive to the white sheet, and a second, equally coated Chessboard Circle gemstone was applied to the black sheet, see position D of FIG. 1.

Coating variant 1 as shown in Table 1 (see below) was chosen as a wavelength-selective PVD coating, in order to have an example of colors with a high saturation.

In an approximately vertical view, the color magenta is obtained for a white seating surface, and the color green for a black seating surface.

As another example, coating variant 2 from Table 2 (see below) was chosen. In an approximately vertical view, yellow is obtained for a white seating surface, and blue for a black seating surface.

In the brilliance measurements, Chessboard Circle gemstones without a wave-length-selective layer were used as comparative examples, in order to demonstrate the importance of the layer to brilliance. The transparent Chessboard Circle gemstones with the UV-curing adhesive were applied directly to the white and black sheets.

TABLE 1
Coating variant 1 for the colors magenta and green;
colors for an approximately vertical view.

| Layer # | Material | Layer thickness [nm] |
|---|---|---|
| 1 | TiO₂ | 143 |
| 2 | SiO₂ | 100 |
| 3 | TiO₂ | 69 |
| 4 | SiO₂ | 30 |
| 5 | TiO₂ | 59 |
| 6 | SiO₂ | 117 |
| 7 | TiO₂ | 28 |
| 8 | SiO₂ | 129 |
| 9 | TiO₂ | 26 |
| 10 | SiO₂ | 129 |
| 11 | TiO₂ | 21 |
| 12 | SiO₂ | 136 |
| 13 | TiO₂ | 27 |
| 14 | SiO₂ | 127 |
| 15 | TiO₂ | 133 |
| 16 | SiO₂ | 65 |

TABLE 2
Coating variant 2 for the colors yellow and blue;
colors for an approximately vertical view.

| Layer # | Material | Layer thickness [nm] |
|---|---|---|
| 1 | TiO₂ | 43.8 |
| 2 | SiO₂ | 38.1 |
| 3 | TiO₂ | 65.2 |
| 4 | SiO₂ | 52 |
| 5 | TiO₂ | 50 |
| 6 | SiO₂ | 83.8 |
| 7 | TiO₂ | 41.6 |
| 8 | SiO₂ | 89.2 |
| 9 | TiO₂ | 39.8 |
| 10 | SiO₂ | 89.6 |
| 11 | TiO₂ | 55.1 |
| 12 | SiO₂ | 39.1 |
| 13 | TiO₂ | 67 |
| 14 | SiO₂ | 138.5 |

### Measuring Set-ups

Measurement of the color location

The L*a*b* color space according to DIN EN ISO 11664-4 was used to measure the color location, and the color distance ΔE was calculated to calculate the color change (see above).

The measuring set-up is shown in FIG. 9. A hemispherical, approximately diffuse illumination was chosen as the light source, and a digital measuring camera was used to detect the color location. A diffuse illumination has the advantage that there is no preferential direction. The decorative ornamental element was illuminated indirectly because an annular light source (4) in FIG. 9 had a light outlet only in the direction of the hemisphere (3). The illumination of the decorative ornamental element was effected by the reflections at the hemisphere. However, the illumination was only approximately diffuse, because an opening (5) in the hemisphere (3) was necessary for measuring with the camera. The hemisphere (3) in FIG. 9 was made of plastic, had a diameter (6) of 300 mm and was provided with a white color at its inner surface (matte acrylic paint of the type RAL9010M). An annular light source of the type Osram L32W/25C Universal White was used as the light source (4). This set-up achieved approximately diffuse light conditions.

The hemisphere (3) had an aperture range (5) of 2×15° for the detection of the color location. A camera of the type Canon EOS400D was used as the measuring camera (2) at a distance (7) of 200 mm from the center of the hemisphere to the front lens of the camera. The decorative ornamental element (1) was placed with a horizontal offset of about 12 mm from the center of the hemisphere. This simulates an “inclined viewing angle” onto the decorative ornamental element, as is often the case when ornamental elements are viewed visually. The direction of the horizontal offset is arbitrary, because the illumination is sufficiently diffuse.

Measurement of Brilliance

The decorative ornamental element is brilliant also upon a color change (see above). In order to show how important the structure of the decorative ornamental element is to brilliance, brilliance measurements were performed with and without a wavelength-selective coating. The measurements were effected in a darkened room in order to avoid further disturbing light influences.

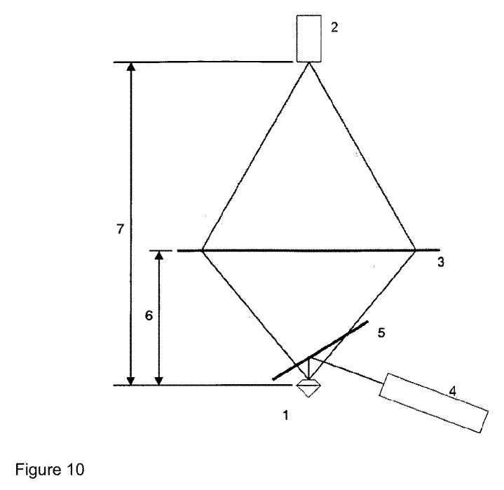

The measuring set-up is shown in FIG. 10. The decorative ornamental element (1) was illuminated with an approximately collimated light source (4) with a beam expansion of 2×0.25° via the semitransparent mirror (5), the Plate Beamsplitter #46-583 of the company Edmund Optics. The approximately collimated light source was realized with a commercially available focusable white LED light projector.

The light reflected by the ornamental element was collected at a distance of 300 mm (6) on the diffuser (3). The diffuser (3) had a size of 600×600 mm² and was a commercially available diffuser sheet, the Luminit Light Shaping Diffuser 60°. At a distance (7) of 1500 mm from the ornamental element to the measuring camera, a measuring camera of the type AVT Manta G-235C with a 12 mm objective was mounted in order to measure the distribution of the reflected light.

The Following Measurements were Performed:

V1: Example according to the invention: Measurement of the color location for white and black seating surfaces with coating variant 1

V2: Example according to the invention: Measurement of the color location for white and black seating surfaces with coating variant 2

V3: Example according to the invention: Measurement of brilliance by measuring the distribution of the reflected light of the decorative ornamental element for white and black seating surfaces with coating variant 2

V4: Comparative Example: Measurement of brilliance by measuring the distribution of the reflected light of the decorative ornamental element for white and black seating surfaces without a wavelength-selective layer

Results of the Measurements:

V1:

The measurement V1 of the color location with coating variant 1 gemstones for white and black seating surfaces had the results:

black seating surface: L*=71.4/a*=−73.4/b*=14.5

white seating surface: L*=39.4/a*=63.5/b*=67.6

The color distance between the black and white seating surfaces was AE=160.6.

V2:

The measurement V2 of the color location with coating variant 2 gemstones for white and black seating surfaces had the results:

black seating surface: L*=71.2/a*=−18.8/b*=−68.3

white seating surface: L*=58.9/a*=57.9/b*=67.2

The color distance between the black and white seating surfaces was ΔE=156.2.

V3:

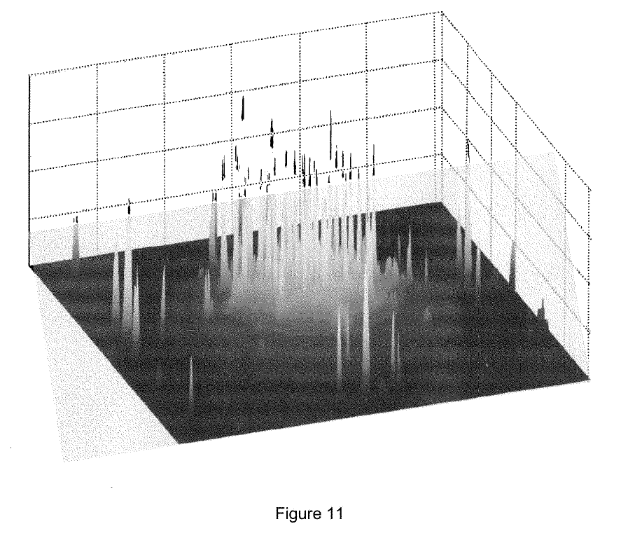

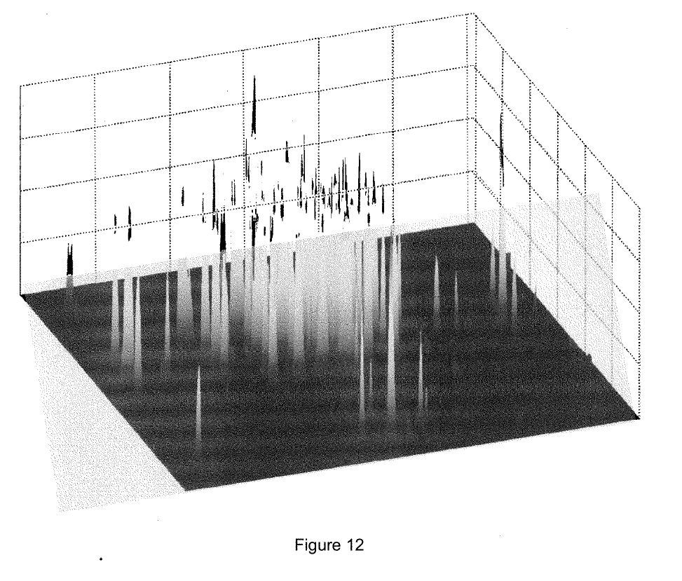

The measurement of the brilliance with gemstones of coating variant 2 for a white seating surface yielded the distribution of FIG. 11. The distribution has many pronounced points of reflected light.

For a black seating surface, the distribution of FIG. 12 was obtained. This distribution also has many pronounced points of reflected light.

V4:

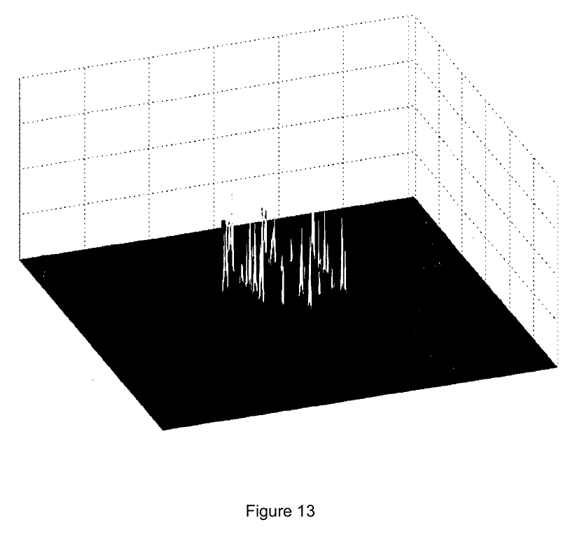

The measurement of the brilliance was performed for white and black seating surfaces even without a wavelength-selective layer. Without a wavelength-selective layer, the reflection was significantly reduced for a white seating surface, as can be seen from FIG. 13.

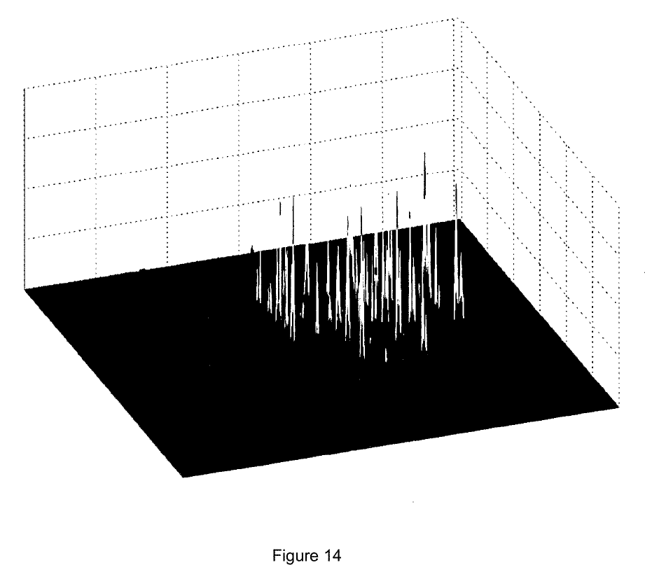

The same applies for a black seating surface. In FIG. 14, the reduced reflection of the light is clearly seen.

Discussion of the Measuring Results:

From the measurements V1 and V2, it can be seen that the color change of the seating surface from black to white leads to significant color changes of the decorative ornamental element. The color of the decorative ornamental element can be influenced by the type of gemstone, the structure of the wavelength-selective layer and the color of the seating surface.

The measurements V3 and V4 clearly show that the wavelength-selective layer is essential to the optical appearance, especially to brilliance. For both white and black seating surfaces, broadly distributed and pronounced points of reflected light, which correspond to a high brilliance (see above), are obtained with the wave-length-selective coating, see FIGS. 11 and 12. Without a wavelength-selective coating (FIGS. 13 and 14), only a few weakly pronounced points of reflected light are present, which correspond to a low brilliance.

1. A decorative ornamental element, containing:
a. a transparent gemstone with a plano-convex geometry,
b. a wavelength-selective layer, and
c. a color-changeable seating surface.

2. The decorative ornamental element according to claim 1, characterized in that said transparent gemstone is made of glass or plastic.

3. The decorative ornamental element according to claim 1 or 2, characterized in that said transparent gemstone is faceted.

4. The decorative ornamental element according to claim 3, characterized in that an inclination angle α of a first facet to a base surface of the transparent gemstone is within an angular range of 10° to 40°.

5. The decorative ornamental element according to claim 3 or characterized in that said wavelength-selective layer is applied:
a) to said gemstone on a planar side opposed to a faceted side, or
b) to said seating surface.

6. The decorative ornamental element according to claim 1, characterized in that said wavelength-selective layer is made of a wavelength-selective coating or a wavelength-selective film.

7. The decorative ornamental element according to claim 6, characterized in that said wavelength-selective layer contains at least one metal and/or metal compound.

8. The decorative ornamental element according to claim 1, characterized in that said wavelength-selective layer reflects and transmits in a wavelength range of from 380 to 780 nm.

9. The decorative ornamental element according to claim 8, characterized in that said wavelength-selective layer additionally transmits at least 20% in a wave-length range of from 360 to 420 nm.

10. The decorative ornamental element according to claim 8, characterized in that said wavelength-selective layer has an average reflectance of less than 75% in a wavelength range of from 400 to 700 nm.

11. The decorative ornamental element according to claim 1, characterized in that an electronically switchable display is used as said seating surface.

12. The decorative ornamental element according to claim 11, characterized in that said electronically switchable display switches between black and white colors.

13. The decorative ornamental element according to claim 1, characterized in that components a) to c) of said decorative ornamental element are bonded together by an adhesive.

14. A process for changing the color of a decorative ornamental element according to claim 1, characterized in that the color of the seating surface is changed by means of an electronic circuit.

15. The decorative ornamental element of claim 7, wherein the wavelength-selective layer has a structure comprising a sequence of SiO₂ and TiO₂ layers.
